(19) United States
(12) Patent Application Publication
(10) Pub. No.: US 2021/0050420 A1
(43) Pub. Date: Feb. 18, 2021

(54) SILICON CARBIDE TRENCH POWER DEVICE

(71) Applicant: SEMICONDUCTOR COMPONENTS INDUSTRIES, LLC, Phoenix, AZ (US)

(72) Inventors: Kwangwon LEE, Incheon (KR); Youngho SEO, Bucheon-si (KR); Martin DOMEIJ, Sollentuna (SE); Kyeongseok PARK, Bucheon (KR)

(73) Assignee: SEMICONDUCTOR COMPONENTS INDUSTRIES, LLC, Phoenix, AZ (US)

(21) Appl. No.: 16/666,771

(22) Filed: Oct. 29, 2019

Related U.S. Application Data
(60) Provisional application No. 62/885,882, filed on Aug. 13, 2019.

(51) Int. Cl. H01L 29/16; H01L 29/66; H01L 29/78

(52) U.S. Cl. CPC H01L 29/1608; H01L 29/7813; H01L 29/66734

(57) ABSTRACT

A power semiconductor device includes a substrate having a body region and a drift layer; a trench formed in the substrate; a gate dielectric structure including a first gate insulation layer having a first dielectric constant and a second gate insulation layer having a second dielectric constant different from the first dielectric constant; and a conductive material provided within the trench over the gate dielectric structure.

### CROSS-REFERENCE TO RELATED APPLICATIONS

This application claims the benefit of U.S. Provisional Patent Application No. 62/885,882, filed on Aug. 13, 2019, the entire contents of which is incorporated herein by reference.

### BACKGROUND

The present disclosure relates to a power semiconductor device, more particularly to a silicon carbide power device having a trench gate structure.

Power semiconductor devices are used in many different industries. Some of these industries, such as telecommunications, computing, and charging systems, are rapidly developing. Those industries would benefit from improved semiconductor device characteristics, including reliability, switching speed, and miniaturization.

Recently, interest in silicon carbide (SiC) has increased greatly since a SiC semiconductor device can boost power handling capability, and its behavior is achieved through the combination of higher power density and better power efficiency. Also power devices with a trench gate structure have become popular since such a structure allows for smaller devices. However, SiC power devices with a trench gate structure exhibit a high gate oxide electric field that could result in the gate oxide breakdown, thereby causing high leakage current and posing a high temperature reverse bias (HTRB) reliability issue.

### BRIEF SUMMARY

In an embodiment, a power semiconductor device includes a substrate having a body region and a drift layer; a trench formed in the substrate; a gate dielectric structure including a first gate insulation layer having a first dielectric constant and a second gate insulation layer having a second dielectric constant different from the first dielectric constant; and a conductive material provided within the trench over the gate dielectric structure.

In an embodiment, the substrate is a silicon carbide substrate. The first gate insulation layer is provided over a sidewall of the trench and the second gate insulation layer is provided over a bottom of the trench.

In an embodiment, the first gate insulation layer includes silicon oxide, and the second gate insulation layer includes dielectric material having a dielectric constant higher than that of the silicon oxide. The second gate insulation layer includes silicon nitride.

In an embodiment, the second gate insulation layer includes aluminum nitride.

In an embodiment, the substrate is a silicon carbide substrate. The first gate insulation layer extends below the body region and into the drift layer.

In an embodiment, the first gate insulation layer includes silicon oxide, and the second gate insulation layer includes dielectric material having a dielectric constant greater than that of the silicon oxide, the second gate insulation layer being configured to reduce electric field buildup in the trench during an operation of the power device.

In an embodiment, the second gate insulation layer includes a lower portion and a side portion that wrap a bottom corner of the conductive material provided in the trench, the side potion being configured to reduce electric field buildup at the bottom corner during the power device operation.

In an embodiment, the side portion of the second gate insulation layer has a height of at least 0.05 um.

In an embodiment, a compensation region is provided below the trench in the drift layer. The compensation region has a conductivity opposite to that of the drift layer.

Another embodiment is directed to a method for fabricating a power semiconductor device. The method includes etching a trench in a substrate having a body region and a drift layer; depositing a first dielectric material over the substrate and into the trench, the first dielectric material having a first dielectric constant; etching the first dielectric material to expose a sidewall of the trench and provide the first dielectric material with a first thickness; forming a second dielectric material over the sidewall of the trench, the second dielectric material having a second dielectric constant different from the first dielectric constant; and providing a conductive material within the trench and over the first and second dielectric materials to from a gate. The first and second dielectric material form a gate dielectric structure for the gate.

In an embodiment, the substrate is a silicon carbide substrate. The first dielectric material is etched to reduce the first dielectric material to a second thickness.

In an embodiment, the first dielectric material is provided with a lower portion and a side portion that wrap a bottom corner of the conductive material.

In an embodiment, the first dielectric material has a dielectric constant of at least 4, and the second dielectric material is silicon oxide.

In an embodiment, the first gate dielectric material includes silicon nitride.

In an embodiment, the first gate dielectric material includes aluminum nitride.

In an embodiment, a compensation region is formed below the trench in the drift layer. The compensation region has a conductivity that is opposite to that of the drift layer.

Yet another embodiment is directed to a method for fabricating a power semiconductor device. The method includes etching a trench in a substrate having a body region and a drift layer; forming a gate dielectric structure including a first gate insulation layer having a first dielectric constant and a second gate insulation layer having a second dielectric constant that is different from the first dielectric constant; and providing a conductive material within the trench and over the gate dielectric structure to make a gate.

In an embodiment, the substrate is a silicon carbide substrate. The first gate insulation layer includes silicon oxide, and the second gate insulation layer includes silicon nitride or aluminum nitride.

In an embodiment, the second gate insulation layer wraps around a bottom corner of the conductive material to reduce electric field buildup at the bottom corner during an operation of the power device.

### BRIEF DESCRIPTION OF THE DRAWINGS

FIG. 1A illustrates a power semiconductor device according to an embodiment.

FIG. 1B illustrates a power semiconductor device according to another embodiment.

FIGS. 2-7 illustrate a method for fabricating a power semiconductor device according to an embodiment.

FIG. 8A illustrates a power semiconductor device fabricated according to an embodiment.

FIG. 8B illustrates a power semiconductor device fabricated according to another embodiment.

### DETAILED DESCRIPTION OF THE INVENTION

Embodiments of the present application relate to silicon carbide power semiconductor devices having a trench gate structure (herein referred to as “SiC trench power device” or “SiC power device”), where the gate is formed in a trench. The SiC trench power device may be a MOSFET, IGBT, or the like; however, for illustrative convenience, the embodiments are described herein using a MOSFET as an example.

In an embodiment, a SiC trench power device includes a trench, and a gate insulation layer within the trench, and a gate material (e.g., polysilicon) over the gate insulation layer. The gate insulation layer includes a plurality of dielectric materials including a low-k dielectric material and a high-k dielectric material. In an embodiment, the low-k dielectric material is silicon oxide (or gate oxide) and is provided on a sidewall of the trench where a channel region of the power device is defined. The power device uses the silicon oxide as the gate insulation over the channel region because of its electrical and thermal stability and also since its characteristics are well understood.

In an embodiment, the high-k dielectric material for the gate insulation layer is silicon nitride, aluminum nitride, or other material that has a higher dielectric constant than the silicon oxide (e.g., a material having a dielectric constant of at least 4). The high-k dielectric material (or silicon nitride) is formed on a bottom of the trench to reduce the electric field on the gate insulation layer during a breakdown voltage mode. If silicon oxide is used entirely as the gate insulation layer, it might experience breakdown since the silicon oxide experiences about 10 times higher electric field in silicon carbide than in silicon.

In an embodiment, the high-k dielectric material is provided over the corners of the gate material since high electric field tends to form at the corners. Accordingly, the high-k dielectric material wraps around bottom corners of the gate material. In an embodiment, a compensation region is provided under the trench to reduce the electric field buildup in the trench. The compensation region is formed by implanting p-type dopants selectively in a drift layer.

A detailed description of embodiments is provided below along with accompanying figures. The scope of this disclosure is limited only by the claims and encompasses numerous alternatives, modifications and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured.

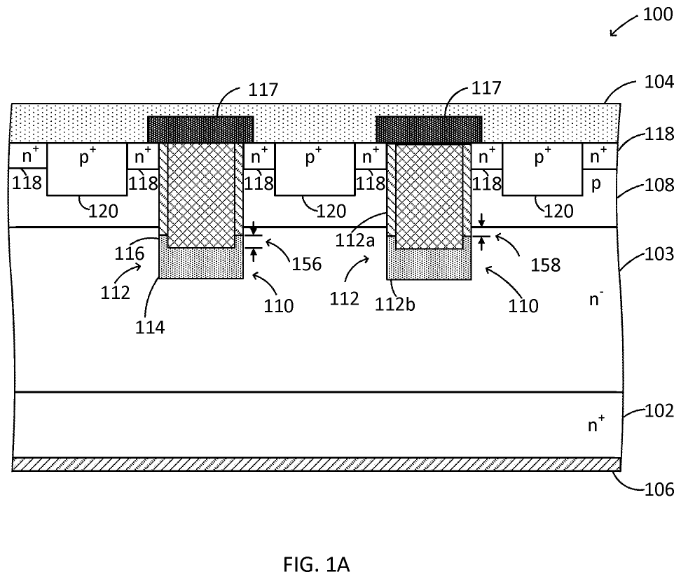

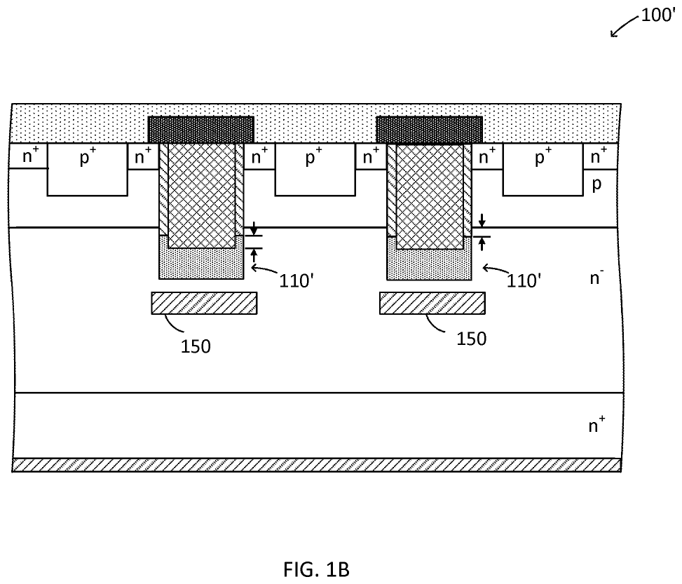

FIG. 1A illustrates a SiC power semiconductor device 100 according to an embodiment. The power device 100 is formed on a silicon carbide substrate 102. In an embodiment, the power device is a SiC trench MOSFET.

The SiC trench MOSFET 100 has a drift layer 103 that has a depth of about 3-20 um depending on implementation, which is substantially thinner the drift layer used for a typical silicon-based power device. As a result the SiC power device 100 experiences significantly less power loss and faster switching speed since the device resistance is dramatically reduced in the SiC power device. In an embodiment, the drift layer 103 is a SiC epitaxial layer of an n-type conductivity.

A source electrode 104 is provided over a front side of the substrate 102. A drain 106 is provided over a backside of the substrate 102. A base or body region 108 of a p-type conductivity is provided over the drift layer 103. The body region has a depth of about 0.8 um according to an embodiment. A gate 110 is formed in a trench that extends from the the top of the body region to about 0.5 um below the body region. The trench may have a depth of about 1.1 um to about 1.7 um, but may have different depths depending on implementation.

In an embodiment, the gate 110 is made of polysilicon.

A gate dielectric structure (or gate insulation layer) 112 is formed over the trench to insulate the gate. The gate dielectric structure includes a first gate insulation layer 112a having a low dielectric constant and a second gate insulation layer 112b having a high dielectric constant. The first gate insulation layer is provided on a sidewall of the trench and formed over a channel region of the gate 110. In an embodiment, the first gate insulation layer 112a is a silicon oxide layer since silicon oxide is well known material and provides the power device with predicable electrical/thermal stability and reliability. In an embodiment, the first gate insulation layer 112a has a thickness of about 0.02 um to about 0.1 um (e.g., about 0.05 um).

The second gate insulation layer 112b is provided over a bottom of the trench to reduce the electric field in the trench. The critical electric field of silicon carbide is much higher than that of silicon, e.g., about 10 times as high (3 MV/cm vs. 0.3 MV/cm). Accordingly, if a low-k dielectric material such as silicon oxide is used as the gate insulation layer in SiC, the resulting high electric field generated in the trench could break the gate insulation layer, particularly during a breakdown voltage mode. The second gate insulation layer 112b having a high dielectric constant reduces the buildup of electric field in the trench. In an embodiment, the second gate insulation layer 112b includes silicon nitride, aluminum nitride, or other material that has a higher dielectric constant than the silicon oxide, which has a dielectric constant of 3.9. In an embodiment, the second gate insulation layer 112b has a dielectric constant of at least 4.

In an embodiment, the second gate insulation layer 112b includes a lower portion 114 and a side portion 116. In an embodiment, the lower portion 114 has a thickness of about 0.2 to about 0.3 um. The side portion 116 is provided over a sidewall of the trench and extends from the lower portion to the first gate insulation layer 112a, wrapping the bottom corners of the gate material in the trench. In an embodiment, the side portion 116 has a height (see numeral 156) of about 0.1 um and thickness of about 0.02 um to about 0.1 um (e.g., about 0.05 um).

In an embodiment, the side portion 116 of the second gate insulation layer is provided about 0.3 um below (see numeral 158) the base region 108. Accordingly, the first gate insulation layer 112a having a low dielectric constant (e.g., silicon oxide) extends below the body region and into the drift layer 103 by about 0.3 um. The silicon oxide extends below the body region to ensure that the entire channel region is covered with the first gate insulation layer 112a.

In an embodiment, a compensation region 150 (see FIG. 1B) is provided below each of the gates 110′ in the drift layer. FIG. 1B illustrates a SiC power device 100′ with the compensation region 150. The compensation region is a p-doped region and has an oppositive conductivity to the drift layer. The compensation region helps reduce electric field buildup in the trench.

Referring back to FIG. 1A, a capping layer 117 of insulation material is formed on top of each of trench gates 110 to protect the gate material provided in the trench from impurities. A barrier metal layer (not shown) may also be provided over the capping layer to prevent diffusion of impurities into the gate.

A plurality of source regions 118 of a highly doped n-type conductivity and a plurality of highly doped p-type regions 120 are formed on the surface of the body region 108, contacting the source electrode 104

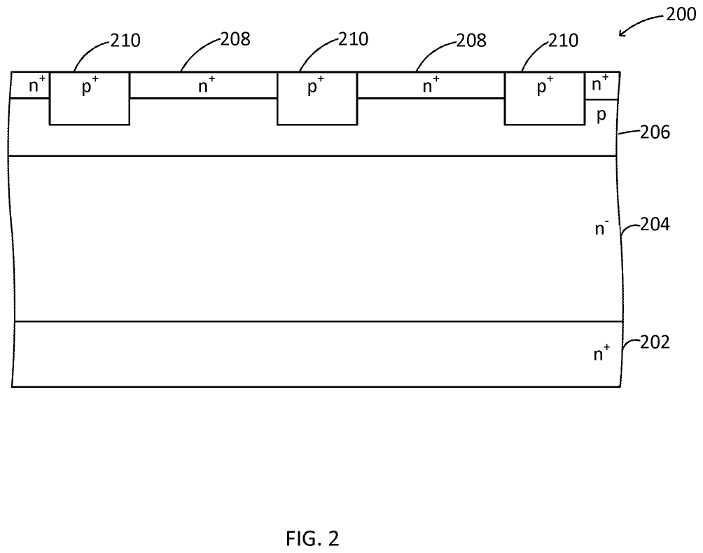

FIGS. 2-7 illustrate a method for fabricating a SiC power semiconductor device, e.g., SiC trench MOSFET, according to an embodiment. A semiconductor substrate 200 having a plurality of doped layers and doped regions is provided (FIG. 2). The substrate includes a highly doped n-type conductivity silicon carbide layer (or n+ layer) 202. A lightly doped n-type silicon carbide layer (n− layer) 204 is formed over the n+ layer 202 by epitaxial growth. A p-type well (or layer) 206 is formed over the n− layer 204. In an embodiment, the p-type well 206 is formed by implanting p-type dopants (e.g., borons) into the n− layer 204. The p-type well 206 serves as a body region of the MOSFET to be formed.

A plurality of highly doped n-type regions 208 is formed on the upper surface of the p-type well 206. The n+ regions are formed by implanting n-type dopants (e.g., phosophorus ions) in the p-type well 206. The n+ regions 208 serve as source regions for the trench

MOSFET. A plurality of highly doped p-type regions 210 is formed on the upper surface of the p-type well (or p-well) 206. The p-type regions 210 are formed by implanting p-type dopants (e.g., aluminum ions) in selective areas of the n+ regions 208.

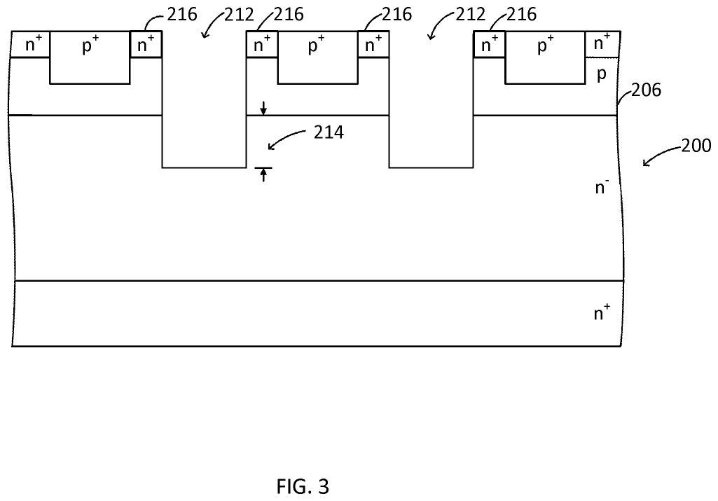

A plurality of trenches 212 is formed by etching the n+ regions 208 (FIG. 3). The trenches extend through the p-well 206. The bottom of the trenches lies about 0.4 to about 0.7 um below the p-well 206, as noted by numberal 214. In an implementation, the trench extends about 0.5 um below the p-well 206. The trenches have a depth of about 1.1 um to about 1.6 um and a width about about 0.3 um to about 0.7 um. In an implementation, the trenches have a depth of about 1.3 um and a width of about 0.5 um. The trenches are used to form gates for the MOSFET. The n+ regions 208 remaining after the trench etch define source regions 216.

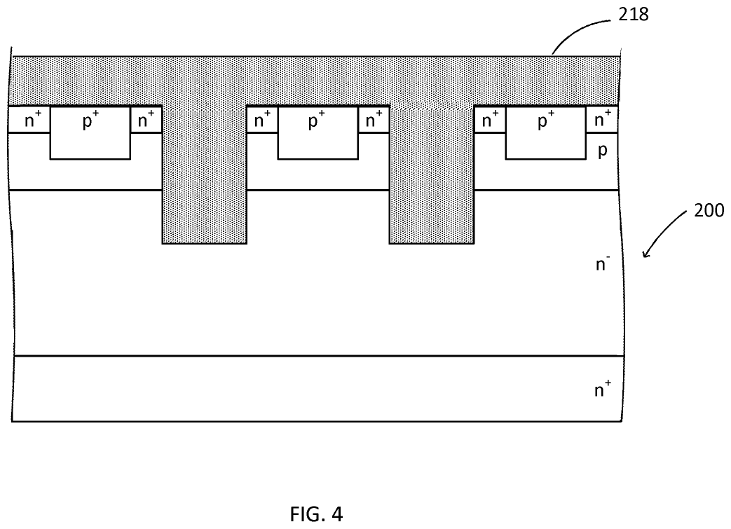

A high-k dielectric material 218 is deposited over the substrate 200 to a thickness of about 0.3 um to about 1 um (FIG. 4). In an embodiment, the high-k dielectric material 218 is deposited to about 0.5 um. The trenches are filled with the high-k dielectric material 218. The high-k dielectric matieral may be deposited to different thicknesses depending on the depth and width of trenches. In an embodiment, the high-k dielectric material is silicon nitride. In another embodiment, the high-k dielectric material is aluminum nitirde or other material with a dielectric constant higher than silicon oxide.

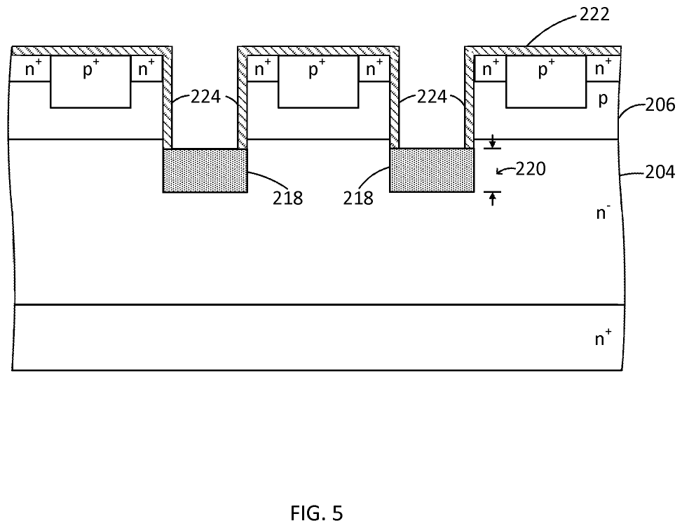

The high-k dielectric material 218 is etched to expose the sidewalls of the trenches (FIG. 5). The etch removes the high-k dielectric material 218 on the trench sidewalls and exposes the silicon carbide surfaces of the p-well 206. The high-k dielectric material 218 remains only at the bottom of the trenches. In an embodiment, the high-k dielectric material 218 is etched to a first height 220, which is about 0.3 to about 0.4 um. The high-k dielectric material is provided at the bottom of the trenches to reduce the electric field buildup in the trench during the MOSFET operation.

The sidewalls of the trenches exposed by etching of the high-k dielectric material 218 define channel regions for the MOSFET. A silicon oxide layer 222 is formed over the substrate 200 including the sidewalls of the trenches. The silicon oxide layer 222 is formed by thermal oxidation to a thickness of about about 0.05 um. The silicon oxide layer 222 covering the sidewalls serves as a first gate insulation layer 224. The first gate insulation layer 224 (or silicon oxide) is used to cover the channels since it provides the power device with predicable electrical/thermal stability and reliability. The first gate insulation layer 224 extends into the n− layer 204 by about 0.2 to about 0.3 um in order to ensure that the entire channel regions are covered by the silicon oxide.

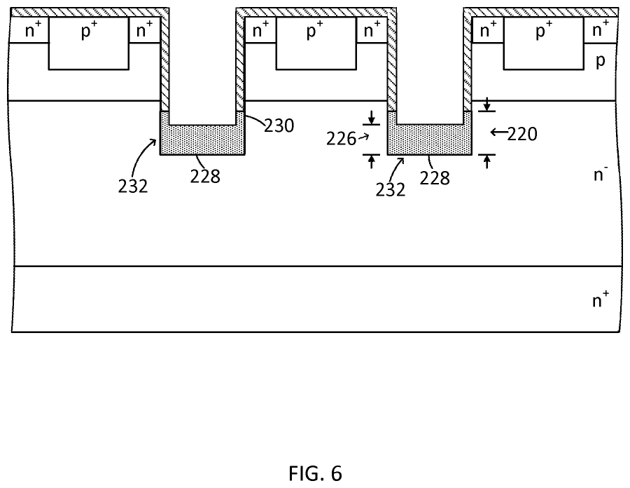

Thereafter, the high-k dielectric material 218 is etched again (FIG. 6). In an embodiment, an anisotropic etch is used to remove a portion of the high k dielectric material provided at the bottom of the trench. The etch reduces the high-k dielectric material 218 to a second height 226 that is less than the first height 220.

As a result, the high-k dielectric material 218 is provided with a lower portion 228 and a side portion 230. The lower portion 228 has a thickness of about 0.2 to about 0.4 um. In an implementation, the thickness is about 0.3 um. The side portion 230 has substantially the same thickness as the gate insulation film 224 (e.g., about 0.05 um), and has a height of about 0.05 um to about 0.15 um. In an implementation, the side portion 230 has a height of about 0.1 um. The lower portion 228 and the side portion 230 wrap the bottom corners of the trench gate and are configured to reduce the electric field in the trench. The lower portion and the side portion define a second gate insulation layer 232.

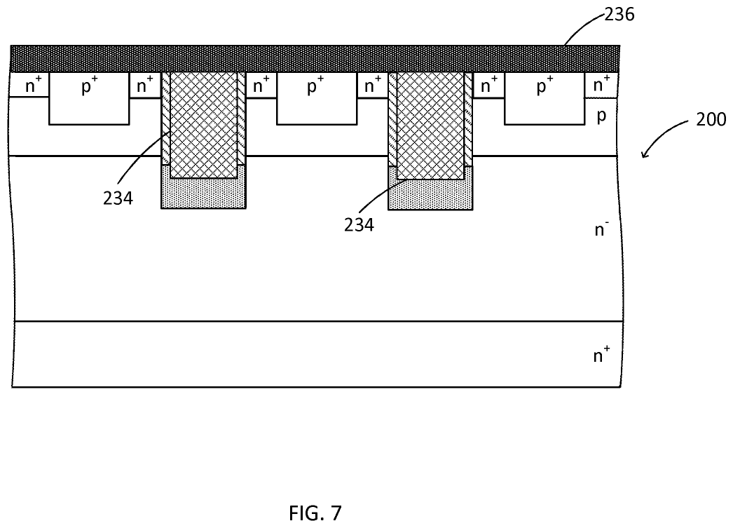

A polysilicon layer is deposited over the substrate 200 and into the trenches to form gates 234 (FIG. 7). The polysilicon is etched, so that it remains only in the trenches, thereby forming the gates. An inter-layer dielectric (ILD) layer 236 are formed over the substrate.

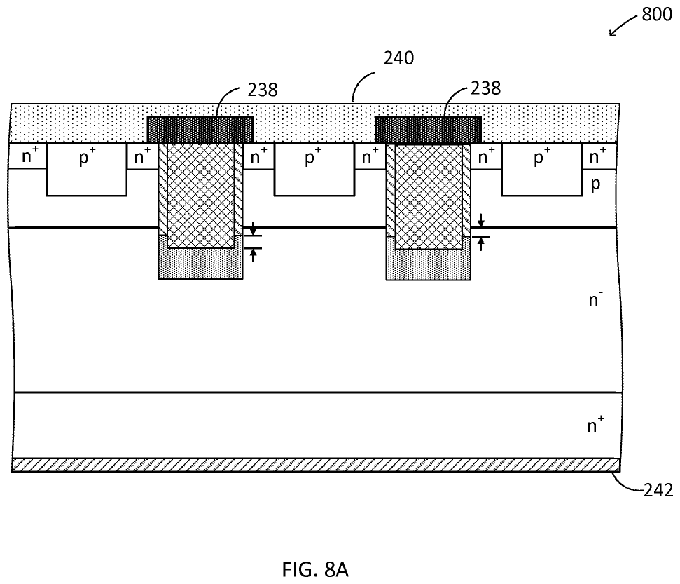

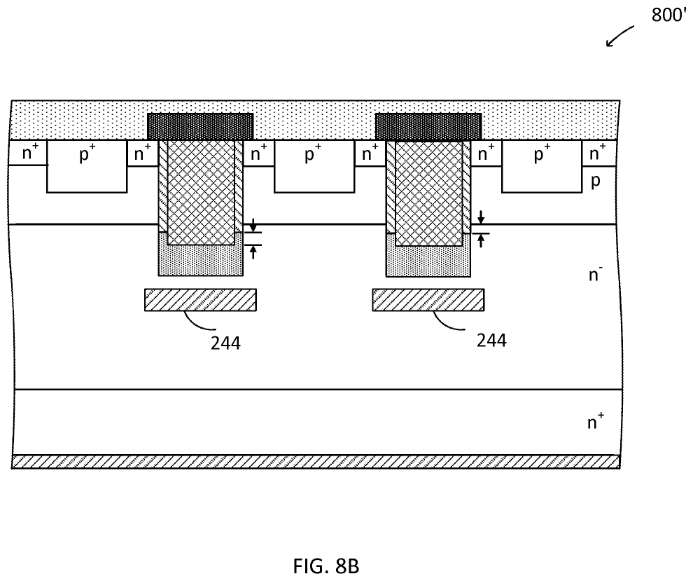

Referring to FIG. 8A, the ILD layer is patterned to form capping layers 238 that enclose the trench openings to protect the gate material from impurities. A metal layer, e.g., aluminum is deposited over the substrate to form a source electrode 240. A drain 242 is formed on a backside of the substrate 200. FIG. 8A illustrates a SiC trench MOSFET 800 formed according to an embodiment, which corresponds the SIC trench MOSFET 100 of FIG. 1A.

In an embodiment, p-type dopants (e.g., boron) may be implanted selectively into the n− layer to form a plurality of compensation regions 244. The compensation region 244 is provided below each of the gates to reduce the electric field buildup in the trench. The implantation may be performed before or after forming the trenches. In an embodiment, the implantation step is performed after forming the trenches and before depositing the high-k dielectric material 218 to prevent unnecessary damages to the high-k dielectric material. FIG. 8B illustrates a SiC trench MOSFET 800′ formed according to an embodiment, which corresponds the SIC trench MOSFET 100′ of FIG. 1B.

Aspects of the present disclosure have been described in conjunction with the specific embodiments thereof that are proposed as examples. Numerous alternatives, modifications, and variations to the embodiments as set forth herein may be made without departing from the scope of the claims set forth below. For example, a power device may have a metal pattern with different thicknesses on the front side and another metal pattern with different thicknesses on the backside to enable lifetime control treatment to be performed from the both sides. Accordingly, embodiments as set forth herein are intended to be illustrative and not limiting.

1. A power semiconductor device, comprising:
a substrate having a body region and a drift layer;
a trench formed in the substrate;
a gate dielectric structure including a first gate insulation layer having a first dielectric constant and a second gate insulation layer having a second dielectric constant different from the first dielectric constant; and
a conductive material provided within the trench over the gate dielectric structure.

2. The power device of claim 1, wherein the substrate is a silicon carbide substrate, and the first gate insulation layer is provided over a sidewall of the trench and the second gate insulation layer is provided over a bottom of the trench.

3. The power device of claim 2, wherein the first gate insulation layer includes silicon oxide, and the second gate insulation layer includes dielectric material having a dielectric constant higher than that of the silicon oxide.

4. The power device of claim 3, wherein the second gate insulation layer includes silicon nitride.

5. The power device of claim 3, wherein the second gate insulation layer includes aluminum nitride.

6. The power device of claim 1, wherein the substrate is a silicon carbide substrate, and the first gate insulation layer extends below the body region and into the drift layer.

7. The power device of claim 1, wherein the first gate insulation layer includes silicon oxide, and the second gate insulation layer includes dielectric material having a dielectric constant greater than that of the silicon oxide, the second gate insulation layer being configured to reduce electric field buildup in the trench during an operation of the power device.

8. The power device of claim 7, wherein the second gate insulation layer includes a lower portion and a side portion that wrap a bottom corner of the conductive material provided in the trench, the side potion being configured to reduce electric field buildup at the bottom corner during the power device operation.

9. The power device of claim 8, wherein the side portion of the second gate insulation layer has a height of at least 0.05 um.

10. The power device of claim 7, further comprising:
a compensation region provided below the trench in the drift layer, the compensation region having a conductivity opposite to that of the drift layer.

11. A method for fabricating a power semiconductor device, the method comprising:
etching a trench in a substrate having a body region and a drift layer;
depositing a first dielectric material over the substrate and into the trench, the first dielectric material having a first dielectric constant;
etching the first dielectric material to expose a sidewall of the trench and provide the first dielectric material with a first thickness;
forming a second dielectric material over the sidewall of the trench, the second dielectric material having a second dielectric constant different from the first dielectric constant; and
providing a conductive material within the trench and over the first and second dielectric materials to from a gate,
wherein the first and second dielectric materials form a gate dielectric structure for the gate.

12. The method of claim 11, wherein the substrate is a silicon carbide substrate, the method further comprising:
etching the first dielectric material to reduce the first dielectric material to a second thickness.

13. The method of claim 12, wherein the first dielectric material is provided with a lower portion and a side portion that wrap a bottom corner of the conductive material.

14. The method of claim 12, wherein the first dielectric material has a dielectric constant of at least 4, and the second dielectric material is silicon oxide.

15. The method of claim 14, wherein the first gate dielectric material includes silicon nitride.

16. The method of claim 14, wherein the first gate dielectric material includes aluminum nitride.

17. The method of claim 12, further comprising:
forming a compensation region below the trench in the drift layer, the compensation region having a conductivity that is opposite to that of the drift layer.

18. A method for fabricating a power semiconductor device, the method comprising:
etching a trench in a substrate having a body region and a drift layer; and
forming a gate dielectric structure including a first gate insulation layer having a first dielectric constant and a second gate insulation layer having a second dielectric constant that is different from the first dielectric constant; and
providing a conductive material within the trench and over the gate dielectric structure to make a gate.

19. The method of claim 18, wherein the substrate is a silicon carbide substrate, the first gate insulation layer includes silicon oxide, and the second gate insulation layer includes silicon nitride or aluminum nitride.

20. The method of claim 18, wherein the second gate insulation layer wraps around a bottom corner of the conductive material to reduce electric field buildup at the bottom corner during an operation of the power device.
